(19) United States
(12) Patent Application Publication
(10) Pub. No.: US 2022/0085208 A1
(43) Pub. Date: Mar. 17, 2022

(54) METHOD FOR MANUFACTURING SEMICONDUCTOR DEVICE AND SEMICONDUCTOR DEVICE

(71) Applicants: Kabushiki Kaisha Toshiba, Tokyo (JP); Toshiba Electronic Devices & Storage Corporation, Tokyo (JP)

(72) Inventors: Kohei OASA, Setagaya Tokyo (JP); Kouta TOMITA, Nonoichi Ishikawa (JP)

(21) Appl. No.: 17/470,592

(22) Filed: Sep. 9, 2021

(30) Foreign Application Priority Data
Sep. 14, 2020 (JP) 2020-153997

(51) Int. Cl. H01L 29/78; H01L 21/306; H01L 21/425; H01L 21/768

(52) U.S. Cl. CPC H01L 29/7813; H01L 21/30604; H01L 29/0878; H01L 21/76831; H01L 21/425

(57) ABSTRACT

A method for manufacturing a semiconductor device includes forming a trench in a first semiconductor layer of a first conductivity type; filling a first insulating film into the trench; etching the first insulating film to cause an upper surface of the first insulating film to recede lower than an opening of the trench and to expose a sidewall of an upper portion of the trench from under the first insulating film; forming a second-conductivity-type semiconductor region in a region of the first semiconductor layer next to the upper portion of the trench by implanting a second-conductivity-type impurity through the sidewall of the upper portion of the trench into the first semiconductor layer and by diffusing the second-conductivity-type impurity; and forming a gate electrode on the first insulating film in the upper portion of the trench after the forming of the second-conductivity-type semiconductor region.

### CROSS-REFERENCE TO RELATED APPLICATION

This application is based upon and claims the benefit of priority from Japanese Patent Application No. 2020-153997, filed on Sep. 14, 2020; the entire contents of which are incorporated herein by reference.

### FIELD

Embodiments described herein relate generally to a method for manufacturing a semiconductor device and a semiconductor device.

### BACKGROUND

It is desirable to design a device in which a gate electrode that is located in a trench controls a channel that conducts a current in the vertical direction of a semiconductor layer by performing the device design after improving the trade-off between the on-resistance and the parasitic capacitance that occurs due to the positional relationship between the gate electrode and the base region. It is also desirable to suppress the fluctuation of the on-resistance and capacitance that may occur in the actual device due to fluctuation when manufacturing.

### BRIEF DESCRIPTION OF THE DRAWINGS

FIG. 1 is a schematic cross-sectional view of a semiconductor device of a first embodiment;

FIG. 2 is a schematic plan view of a configuration of a portion of the semiconductor device of the first embodiment;

FIG. 3 to FIG. 11 are schematic cross-sectional views showing a method for manufacturing the semiconductor device of the first embodiment;

FIGS. 12A and 12B are schematic cross-sectional views of the semiconductor device of the first embodiment;

FIG. 13 is a graph illustrating simulation results of Ron×Qgd characteristics of the semiconductor device of the first embodiment;

FIG. 14 is a schematic cross-sectional view of a semiconductor device of a second embodiment;

FIG. 15 is a schematic cross-sectional view of a semiconductor device of a third embodiment;

FIG. 16 is a schematic cross-sectional view showing a method for manufacturing the semiconductor device of the third embodiment;

FIG. 17 is a schematic plan view of a configuration of a portion of a semiconductor device of a fourth embodiment;

FIG. 18 is an A-A′ cross-sectional view of FIG. 17; and

FIG. 19 is a B-B′ cross-sectional view of FIG. 17.

### DETAILED DESCRIPTION

According to one embodiment, a method for manufacturing a semiconductor device includes forming a trench in a first semiconductor layer of a first conductivity type; filling a first insulating film into the trench; etching the first insulating film to cause an upper surface of the first insulating film to recede lower than an opening of the trench and to expose a sidewall of an upper portion of the trench from under the first insulating film; forming a second-conductivity-type semiconductor region in a region of the first semiconductor layer next to the upper portion of the trench by implanting a second-conductivity-type impurity through the sidewall of the upper portion of the trench into the first semiconductor layer and by diffusing the second-conductivity-type impurity; and forming a gate electrode on the first insulating film in the upper portion of the trench after the forming of the second-conductivity-type semiconductor region.

Embodiments will now be described with reference to the drawings. The same components in the drawings are marked with the same reference numerals.

Although the first conductivity type is described as an n-type and the second conductivity type is described as a p-type in embodiments described below, the first conductivity type may be the p-type; and the second conductivity type may be the n-type.

### First Embodiment

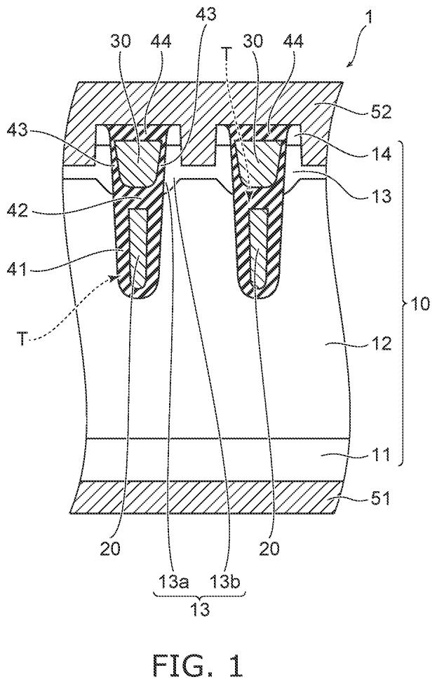

FIG. 1 is a schematic cross-sectional view of a semiconductor device 1 of a first embodiment.

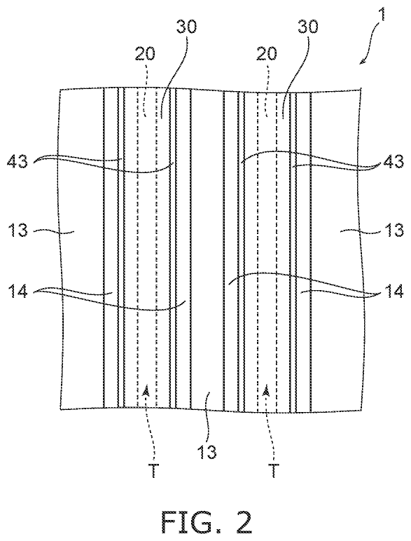

FIG. 2 is a schematic plan view of the configuration of a portion of the semiconductor device 1 of the first embodiment.

The semiconductor device 1 includes a semiconductor part 10, a drain electrode (a first electrode) 51, a source electrode (a second electrode) 52, a gate electrode (a control electrode) 30, and a field plate electrode 20. The drain electrode 51 is located at one surface of the semiconductor part 10; and the source electrode 52 is located at the other surface of the semiconductor part 10. The semiconductor device 1 is a vertical semiconductor device in which a current is caused to flow in a direction (the vertical direction) connecting the drain electrode 51 and the source electrode 52 by the control of the gate electrode 30.

The material of the semiconductor part 10 is, for example, silicon. Or, the material of the semiconductor part 10 may be, for example, silicon carbide, gallium nitride, etc.

The semiconductor part 10 includes an n⁺-type drain layer (or substrate) 11, an n-type drift layer (a first semiconductor layer) 12, a p-type base region (a second-conductivity-type semiconductor region) 13, and an n⁺-type source region (a first-conductivity-type semiconductor region) 14.

The drift layer 12 is located on the drain layer 11. The n-type impurity concentration of the drain layer 11 and the n-type impurity concentration of the source region 14 are greater than the n-type impurity concentration of the drift layer 12. The base region 13 is located on the drift layer 12; and the source region 14 is located on the base region 13.

Multiple trenches T are formed in the semiconductor part 10. The sidewalls of the trenches T are next to the source region 14, the base region 13, and the drift layer 12. The bottoms of the trenches T are positioned in the drift layer 12.

As shown in FIG. 2, the trench T, the gate electrode 30, the field plate electrode 20, the source region 14, and the base region 13 are formed in stripe shapes that extend in a first direction (in FIG. 2, the vertical direction) orthogonal to the depth direction of the trench T.

As shown in FIG. 1, the gate electrode 30 and the field plate electrode 20 are located in the trench T. The gate electrode 30 is located on the field plate electrode 20 in the trench T. An insulating film 42 is located between the gate electrode 30 and the field plate electrode 20 in the trench T. An insulating film 41 is located between the field plate electrode 20 and the bottom of the trench T and between the field plate electrode 20 and the sidewall of the trench T.

The gate electrode 30 is next to a portion of the source region 14 and a portion of the base region 13 with a gate insulating film 43 interposed. The gate insulating film 43 is located between the gate electrode 30 and the source region 14 and between the gate electrode 30 and the base region 13.

The base region 13 faces the side surface of the gate electrode 30 via the gate insulating film 43. An n-type channel (an inversion layer) can be formed in the portion of the base region 13 that faces the gate electrode 30 by applying a voltage that is not less than a threshold to the gate electrode 30.

The base region 13 includes a first portion 13a and a second portion 13b. The first portion 13a is positioned between the gate insulating film 43 and the second portion 13b and contacts the gate insulating film 43. The first portion 13a is next to the gate insulating film 43 (the sidewall of the trench T). The p-type impurity concentration of the first portion 13a is greater than the p-type impurity concentration of the second portion 13b.

According to the first embodiment, the boundary between the first portion 13a and the gate insulating film 43 protrudes lower than the second portion 13b. The lowermost end of the base region 13 is positioned at the boundary between the first portion 13a and the gate insulating film 43. The lowermost end of the base region 13 is positioned lower than the lowermost end of the gate electrode 30.

The drain electrode 51 is located at the back surface of the drain layer 11. The drain electrode 51 contacts the drain layer 11 and is electrically connected with the drain layer 11.

The source electrode 52 is located on the upper surface of the semiconductor part 10. The source electrode 52 contacts the upper surface and side surface of the source region 14 and is electrically connected with the source region 14. Also, the source electrode 52 contacts the base region 13 and is electrically connected with the base region 13. The p-type impurity concentration of the portion of the base region 13 that contacts the source electrode 52 is greater than the p-type impurity concentration of the first portion 13a and the p-type impurity concentration of the second portion 13b.

An insulating film 44 is located between the source electrode 52 and the gate electrode 30. The gate electrode 30 is electrically connected with a not-illustrated gate interconnect. For example, the field plate electrode 20 is electrically connected with the source electrode 52. The field plate electrode 20 relaxes the distribution of the electric field of the drift layer 12 in the gate off-state.

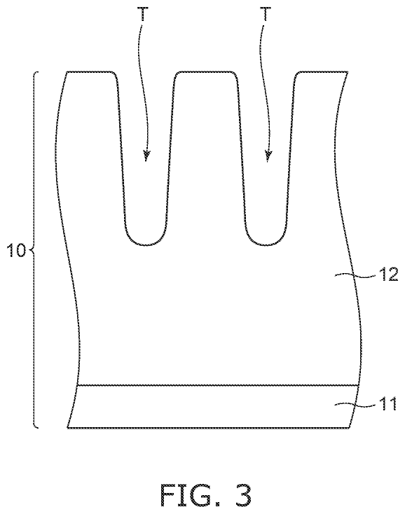

A method for manufacturing the semiconductor device 1 of the first embodiment will now be described with reference to FIGS. 3 to 11.

As shown in FIG. 3, the multiple trenches T are formed in the drift layer 12. The trench T is formed in a stripe shape that extends in the first direction (in FIG. 3, the direction extending through the page surface) orthogonal to the depth direction of the trench T. For example, the trench T is formed by RIE (Reactive Ion Etching) using a not-illustrated mask. The bottom of the trench T does not reach the drain layer 11 and is positioned in the drift layer 12.

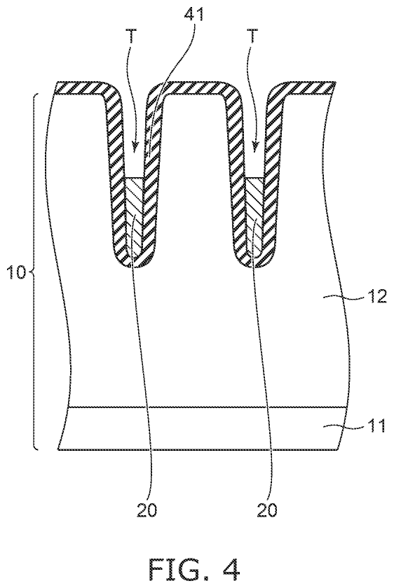

As shown in FIG. 4, a conductive body that is the material of the field plate electrode 20 is filled into the trench T with the insulating film 41 interposed. The insulating film 41 is formed along the inner wall (the bottom and the sidewall) of the trench T and the upper surface of the drift layer 12. The conductive body is filled into the space in the trench T at the inner side of the insulating film 41 and is subsequently subjected to, for example, etch-back. The etch-back causes the upper surface of the conductive body to recede to be positioned in the trench T lower than the opening of the trench T. The insulating film 41 is, for example, a silicon oxide film. The field plate electrode 20 is, for example, polycrystalline silicon.

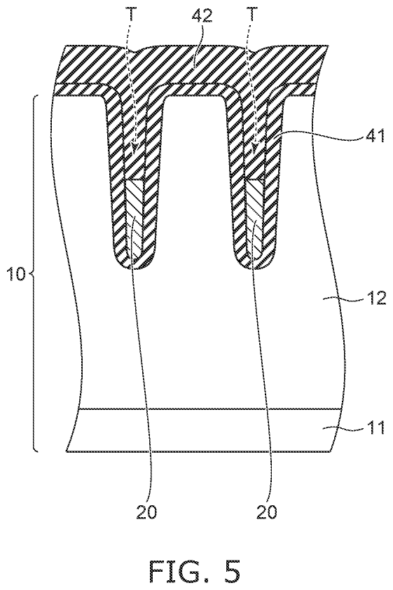

A space that is surrounded with the insulating film 41 above the field plate electrode 20 in the trench T is ensured. The insulating film 42 shown in FIG. 5 is formed on the semiconductor part 10 to fill the space. The insulating film 42 is, for example, a silicon oxide film. The interior of the trench T is filled with the field plate electrode 20 and the insulating film 42 with the insulating film 41 interposed.

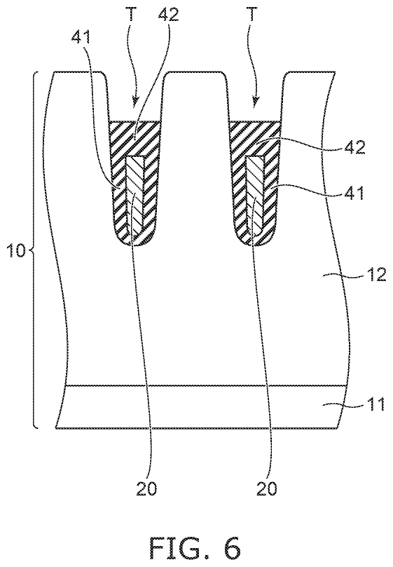

When forming the insulating film 42, the upper surface of the insulating film 42 is positioned higher than the opening of the trench T. Subsequently, the upper surface of the insulating film 42 is caused to recede by etching the insulating film 42. As shown in FIG. 6, the upper surface of the insulating film 42 is caused to recede lower than the opening of the trench T. The insulating film 41 that is formed at the sidewall of the trench T is, for example, the same silicon oxide film as the insulating film 42; therefore, the insulating film 41 also is etched when etching the insulating film 42. Thereby, the sidewall of the upper portion of the trench T is exposed from under the insulating film 41 and the insulating film 42. The insulating film 41 that is formed at the upper surface of the drift layer 12 also is removed. The insulating film 42 that remains in the trench T covers the upper surface of the field plate electrode 20.

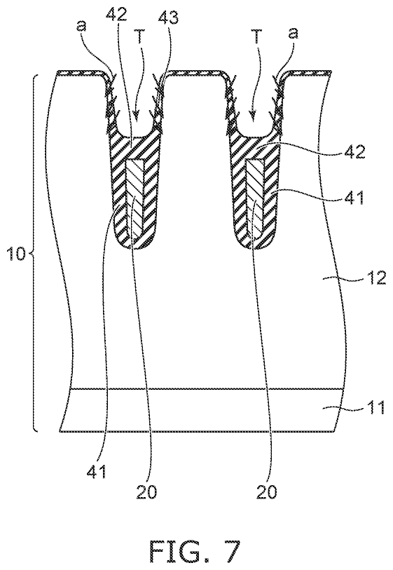

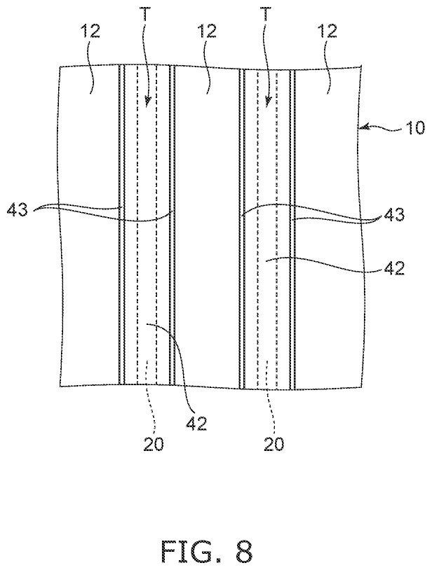

The gate insulating film 43 is formed at the exposed sidewall of the upper portion of the trench T as shown in FIGS. 7 and 8. The gate insulating film 43 is, for example, a silicon oxide film formed by thermal oxidation. The gate insulating film 43 is also formed at the upper surface of the drift layer 12. A space that is surrounded with the gate insulating film 43 remains in the upper portion of the trench T.

After forming the gate insulating film 43, a p-type impurity is implanted by ion implantation through the sidewall of the upper portion of the trench T into the semiconductor part 10 (the drift layer 12). The p-type impurity is implanted into the drift layer 12 through the gate insulating film 43. The p-type impurity is, for example, boron. In FIG. 7, the implantation directions of the p-type impurity are schematically illustrated by arrows a. The p-type impurity is implanted obliquely downward through the sidewall of the upper portion of the trench T into the drift layer 12 to be oblique to the thickness direction and the front surface of the semiconductor part 10. Or, the gate insulating film 43 may be formed after performing the ion implantation.

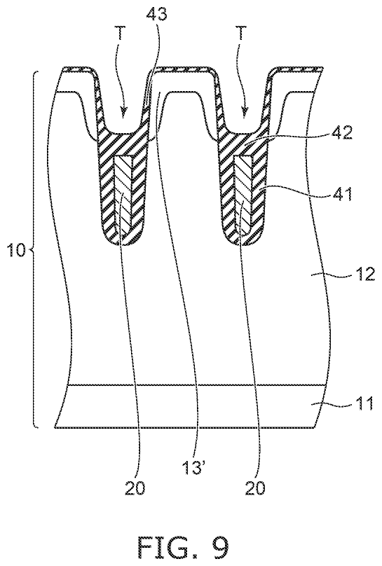

As shown in the plan view of FIG. 8, the trenches T extend in stripe shapes; and one trench T includes two sidewalls. In one trench T, the p-type impurity is implanted into the drift layer 12 through each of the two sidewalls of the upper portion of the one trench T. FIG. 9 schematically illustrates a region 13′ into which the p-type impurity is implanted.

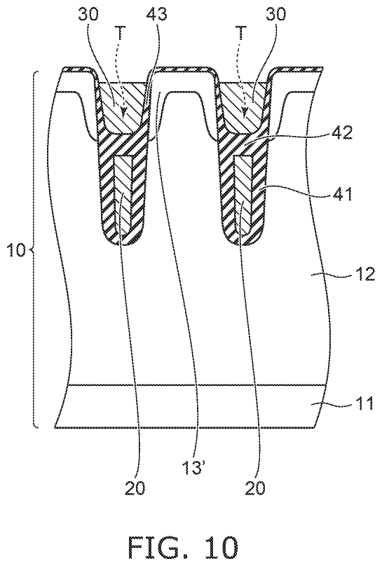

After the ion implantation as shown in FIG. 10, the gate electrode 30 is formed on the insulating film 42 in the upper portion of the trench T. The conductive body that is used as the material of the gate electrode 30 is, for example, polycrystalline silicon.

The conductive body that is used as the material of the gate electrode 30 is formed on the semiconductor part 10 so that the upper surface of the conductive body is positioned higher than the opening of the trench T; subsequently, the upper surface of the gate electrode 30 is caused to recede lower than the opening of the trench T. The upper surface of the gate electrode 30 is positioned in the trench T to be lower than the opening of the trench T.

After forming the gate electrode 30, an n-type impurity is implanted through the upper surface of the semiconductor part 10 into the semiconductor part 10. The n-type impurity is implanted in a direction that is substantially perpendicular to the upper surface of the semiconductor part 10. The n-type impurity is, for example, phosphorus or arsenic.

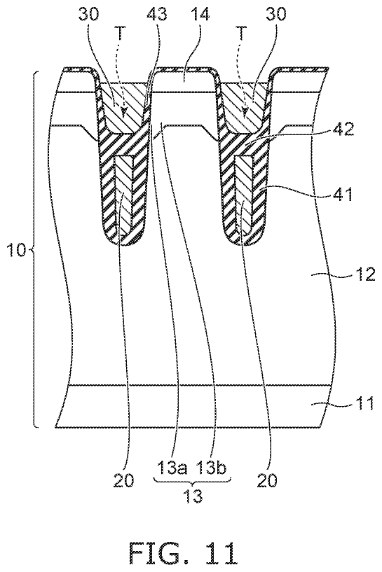

Subsequently, the p-type impurity and the n-type impurity that are implanted into the semiconductor part 10 are diffused by heat treatment. Thereby, as shown in FIG. 11, the p-type base region 13 is formed in the region of the semiconductor part 10 next to the sidewall of the upper portion of the trench T; and the n-type source region 14 is formed on the base region 13.

The insulating film 44 is filled into the trench T on the gate electrode 30. The insulating film 44 is formed to cover the upper surface of the semiconductor part 10; subsequently, the insulating film 44 that is on the upper surface of the semiconductor part 10 (the upper surface of the source region 14) is removed. At this time, the gate insulating film 43 that is formed at the upper surface of the source region 14 also is removed; and the upper surface of the source region 14 is exposed.

A contact trench that reaches the base region 13 from the exposed upper surface of the source region 14 is formed; subsequently, the source electrode 52 is formed in the contact trench and on the semiconductor part 10. The drain electrode 51 is formed at the back surface of the drain layer 11.

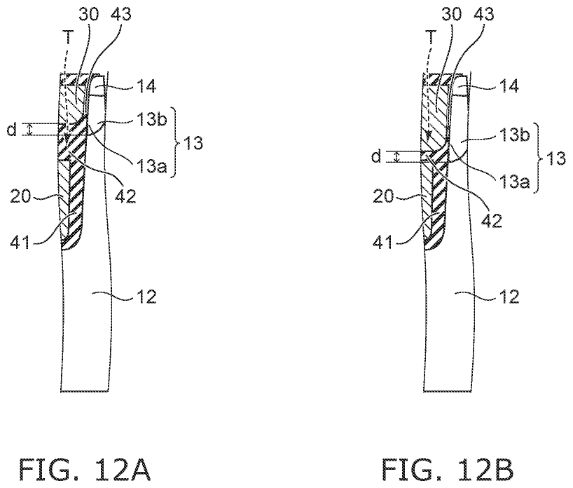

FIGS. 12A and 12B are schematic cross-sectional views of a portion of the semiconductor device 1 of the first embodiment next to the gate electrode 30 and the base region 13.

The gate electrode 30 of FIG. 12A is thinner than the gate electrode 30 of FIG. 12B; and the lower end of the gate electrode 30 (the upper surface of the insulating film 42) of FIG. 12A is positioned higher than the lower end of the gate electrode 30 (the upper surface of the insulating film 42) of FIG. 12B. The thickness of the gate electrode 30 is the thickness along the depth direction of the trench T. The upper surface of the gate electrode 30 of FIG. 12A and the upper surface of the gate electrode 30 of FIG. 12B are positioned at the same position (level).

According to embodiments, the p-type impurity is implanted through the sidewall of the upper portion of the trench T into the drift layer 12 (the process of FIG. 7) before filling the gate electrode 30 into the space in the upper portion of the trench T. Thereby, even when the position of the upper surface of the insulating film 42 that determines the position of the lower end of the gate electrode 30 fluctuates when the insulating film 42 is etched, the position of the lower end of the base region 13 also changes to follow the position of the upper surface of the insulating film 42, i.e., the position of the lower end of the gate electrode 30.

As shown in FIGS. 12A and 12B, even when the position of the lower end of the gate electrode 30 fluctuates, a distance d in the vertical direction (the current path direction) between the lower end of the gate electrode 30 and the lower end of the base region 13 can be substantially constant. Accordingly, a robust structure can be realized in which the device characteristics are not sensitive to the fluctuation when manufacturing.

As shown in FIG. 7, the p-type impurity is implanted in an oblique direction through the sidewall of the upper portion of the trench T; thereby, as shown in FIG. 9, the implantation region 13′ of the p-type impurity is formed to be deeper proximate to the sidewall of the trench T. Therefore, after the thermal diffusion as shown in FIGS. 10 and 1, the first portion 13a of the base region 13 that is next to the gate insulating film 43 (the sidewall of the trench T) protrudes lower than the second portion 13b that is more distant than the first portion 13a to the gate insulating film 43 (the sidewall of the trench T). This makes it possible to reduce a parasitic capacitance (a gate-drain capacitance) Cgd between the gate electrode 30 and the drift layer 12.

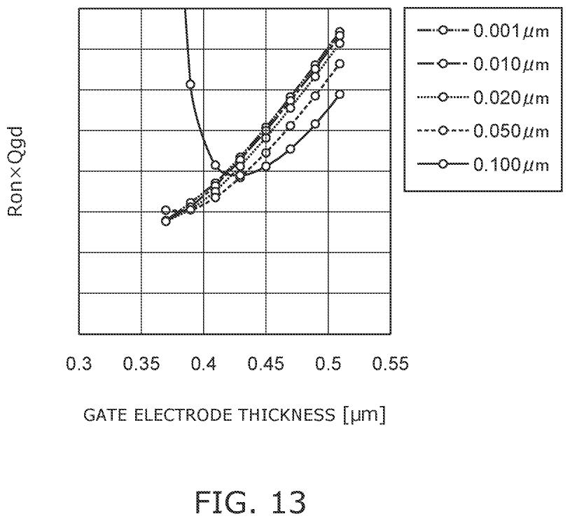

FIG. 13 is a graph illustrating simulation results of Ron×Qgd characteristics of the semiconductor device 1 of the first embodiment. Ron is the on-resistance. Qgd is the gate-drain charge amount that is regarded as an important index of the switching performance. The horizontal axis is the thickness of the gate electrode 30. The thickness of the gate electrode 30 is changed by fixing the position of the upper surface of the gate electrode 30 and by changing the position of the lower end.

The solid line illustrates the characteristic when the protrusion amount of the deepest portion (the portion next to the sidewall of the trench T) with respect to the shallowest portion of the lower surface of the base region 13 was 0.100 μm.

The dashed line illustrates the characteristic when the protrusion amount of the base region 13 described above was 0.050 μm.

The dotted line illustrates the characteristic when the protrusion amount of the base region 13 described above was 0.020 μm.

The single dot-dash line illustrates the characteristic when the protrusion amount of the base region 13 described above was 0.010 μm.

The double dot-dash line illustrates the characteristic when the protrusion amount of the base region 13 described above was 0.001 μm.

The position of the shallowest portion of the lower surface of the base region 13 was the same for these five cases.

It can be seen from the simulation results of FIG. 13 that if the thickness of the gate electrode 30 is in a constant range, Ron×Qgd can be reduced as the protrusion amount of the portion of the base region 13 next to the sidewall of the trench T is increased.

The protrusion amount of the portion of the base region 13 next to the sidewall of the trench T can be adjusted by controlling the ion implantation conditions of the p-type impurity implanted through the sidewall of the trench T into the drift layer 12 such as the implantation angle, the acceleration, etc. Also, the protrusion amount of the portion of the base region 13 next to the sidewall of the trench T can be adjusted by implanting the p-type impurity multiple times while changing the angle and/or the velocity.

### Second Embodiment

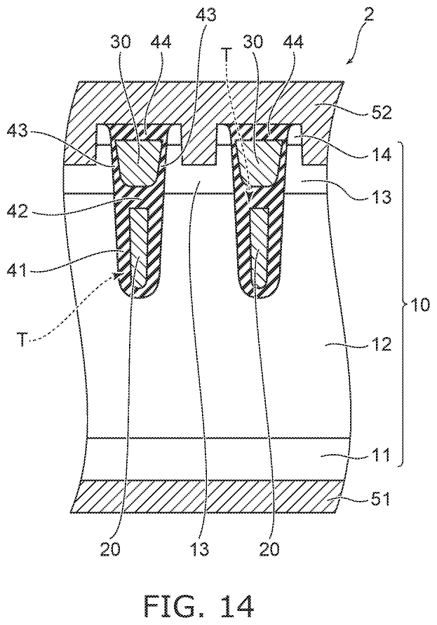

FIG. 14 is a schematic cross-sectional view of a semiconductor device 2 of a second embodiment.

For example, by increasing the acceleration of the p-type impurity, the lower surface of the base region 13 can be substantially flat as shown in FIG. 14 without the portion of the base region 13 next to the sidewall of the trench T protruding downward. In such a case as well, the p-type impurity is implanted through the sidewall of the upper portion of the trench T after causing the upper surface of the insulating film 42 to recede and before forming the gate electrode 30; therefore, even if the position of the upper surface of the insulating film 42 that determines the position of the lower end of the gate electrode 30 fluctuates, the distance between the lower end of the gate electrode 30 and the lower end of the base region 13 can be substantially constant.

### Third Embodiment

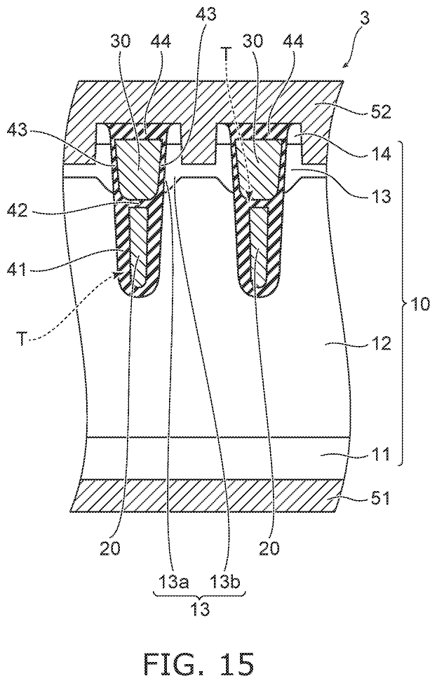

FIG. 15 is a schematic cross-sectional view of a semiconductor device 3 of a third embodiment.

As shown in FIG. 15, the lower end of the gate electrode 30 may be positioned lower than the lower end of the first portion 13a of the base region 13 next to the sidewall of the trench T. In the semiconductor device 3, compared to a structure in which the lower end of the base region 13 protrudes lower than the lower end of the gate electrode 30, the surface area of the base region 13 that faces the gate electrode 30 can be increased; therefore, the on-resistance can be reduced.

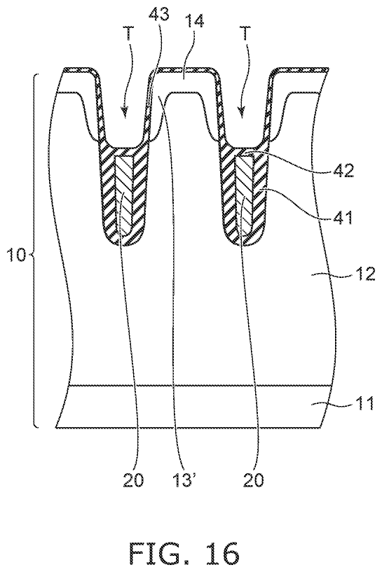

This structure is formed by performing additional etching of the insulating film 42 to cause the upper surface of the insulating film 42 to recede lower than the lower end of the base region 13 as shown in FIG. 16 after forming the base region 13 by implanting the p-type impurity through the sidewall of the upper portion of the trench T and before filling the gate electrode 30 onto the insulating film 42 in the trench T as described above. Although fluctuation may occur in the etching amount (the recessed amount of the upper surface of the insulating film 42) in the additional etching of the insulating film 42, the additional etching amount is slight compared to the etching amount of the first etching of the insulating film 42; and the fluctuation of the position of the lower end of the gate electrode 30 due to the additional etching is small and is not enough to affect the device characteristics.

### Fourth Embodiment

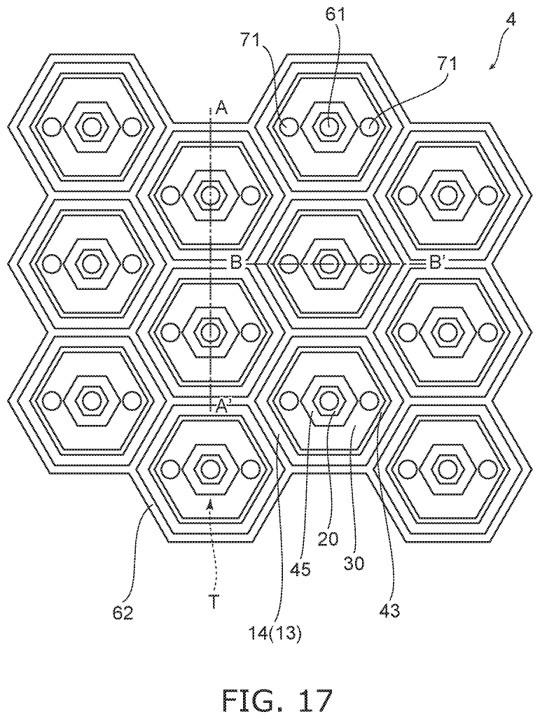

FIG. 17 is a schematic plan view of the configuration of a portion of a semiconductor device 4 of a fourth embodiment.

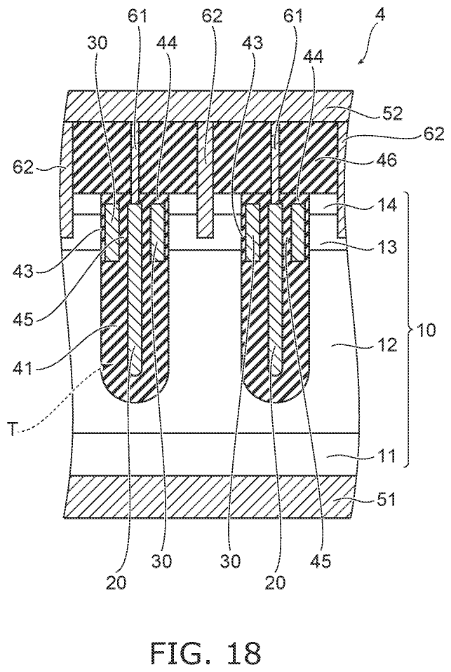

FIG. 18 is an A-A′ cross-sectional view of FIG. 17.

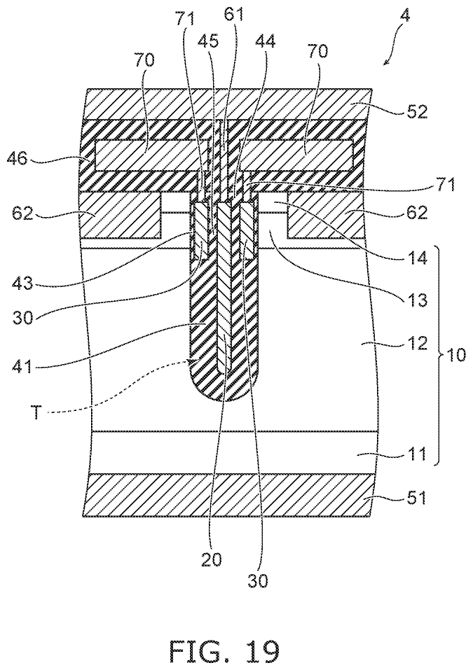

FIG. 19 is a B-B′ cross-sectional view of FIG. 17.

The trench T that includes the gate electrode 30 in the interior of the trench T is not limited to stripe-shaped and may be a polygonal hole that includes three or more sidewalls. FIG. 17 shows an example in which the trench T is formed as, for example, a hexagonal hole. One trench T includes six sidewalls. The p-type base region 13 is formed by implanting the p-type impurity through each of the six sidewalls into the drift layer 12 similarly to the process shown in FIG. 7 described above.

In such a case as well, even if the position of the lower end of the gate electrode 30 fluctuates, the distance in the vertical direction (the current path direction) between the lower end of the gate electrode 30 and the lower end of the base region 13 can be substantially constant, and a robust structure can be realized in which the device characteristics are not sensitive to the fluctuation when manufacturing.

The field plate electrode 20 is located along the central-axis direction of the trench T at the center position of the trench T. The gate electrode 30 surrounds the perimeter of the upper portion of the field plate electrode 20 in the upper portion of the trench T. An insulating film 45 is located between the field plate electrode 20 and the gate electrode 30.

The insulating film 44 is located on the field plate electrode 20 and on the gate electrode 30 in the trench T. An insulating film 46 is located on the semiconductor part 10 and on the insulating film 44. The source electrode 52 is located on the insulating film 46.

The field plate electrode 20 is connected with the source electrode 52 via a metal plug 61 that extends through the insulating film 46 and the insulating film 44.

As shown in FIG. 19, a gate interconnect 70 is located in the insulating film 46. The gate interconnect 70 is connected with the gate electrode 30 via a metal plug 71 that extends from the lower surface of the gate interconnect 70 through the insulating film 46 and the insulating film 44 toward the gate electrode 30.

As shown in FIG. 18, the source region 14 and the base region 13 are connected with the source electrode 52 via a metal plug 62 that extends through the insulating film 46. As shown in FIG. 17, the metal plug 62 surrounds the perimeter of the hexagonal trench T.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A method for manufacturing a semiconductor device, comprising:
forming a trench in a first semiconductor layer of a first conductivity type;
filling a first insulating film into the trench;
etching the first insulating film to cause an upper surface of the first insulating film to recede lower than an opening of the trench and to expose a sidewall of an upper portion of the trench from under the first insulating film;
forming a second-conductivity-type semiconductor region in a region of the first semiconductor layer next to the upper portion of the trench by implanting a second-conductivity-type impurity through the sidewall of the upper portion of the trench into the first semiconductor layer and by diffusing the second-conductivity-type impurity; and
forming a gate electrode on the first insulating film in the upper portion of the trench after the forming of the second-conductivity-type semiconductor region.

2. The method according to claim 1, further comprising:
forming a second insulating film at the sidewall of the upper portion of the trench,
the second-conductivity-type impurity being implanted into the first semiconductor layer through the second insulating film.

3. The method according to claim 1, further comprising:
filling a conductive body into the trench before the filling of the first insulating film into the trench.

4. The method according to claim 1, further comprising:
after the forming of the second-conductivity-type semiconductor region and before the filling of the gate electrode, etching the first insulating film in the trench to cause the upper surface of the first insulating film to recede lower than a lower end of the second-conductivity-type semiconductor region.

5. The method according to claim 1, wherein
the trench includes two sidewalls extending in a first direction orthogonal to a depth direction of the trench, and
the second-conductivity-type impurity is implanted into the first semiconductor layer through each of the two sidewalls.

6. The method according to claim 1, wherein
the trench is a polygonal hole including three or more sidewalls, and
the second-conductivity-type impurity is implanted into the first semiconductor layer through each of the three or more sidewalls.

7. The method according to claim 6, wherein
the hole is a hexagon including six of the sidewalls.

8. A semiconductor device, comprising:
a semiconductor part including a first semiconductor layer of a first conductivity type;
a first insulating film formed in the semiconductor part;
a gate electrode located on the first insulating film;
a second-conductivity-type semiconductor region located on the first semiconductor layer in a region of the semiconductor part next to the gate electrode;
a second insulating film located between the gate electrode and the second-conductivity-type semiconductor region; and
a first-conductivity-type semiconductor region located on the second-conductivity-type semiconductor region,
the second-conductivity-type semiconductor region including a first portion and a second portion,
the first portion being positioned between the second insulating film and the second portion and contacting the second insulating film,
a second-conductivity-type impurity concentration of the first portion being greater than a second-conductivity-type impurity concentration of the second portion.

9. The device according to claim 8, wherein
a boundary between the first portion and the second insulating film protrudes lower than the second portion.

10. The device according to claim 8, wherein
a lower end of the second-conductivity-type semiconductor region is positioned lower than a lower end of the gate electrode.

11. The device according to claim 8, wherein
a lowermost end of the second-conductivity-type semiconductor region is positioned at a boundary between the first portion and the second insulating film.

12. The device according to claim 8, further comprising:
a first electrode electrically connected with the first semiconductor layer; and
a second electrode electrically connected with the first-conductivity-type semiconductor region and the second-conductivity-type semiconductor region.

13. The device according to claim 12, further comprising:
a field plate electrode located in the first insulating film,
the field plate electrode being electrically connected with the second electrode.

14. The device according to claim 8, wherein
the gate electrode, the first-conductivity-type semiconductor region, and the second-conductivity-type semiconductor region are formed in stripe shapes.

15. The device according to claim 7, wherein
the gate electrode is located in a hole formed in the semiconductor part, and
the hole includes three or more sidewalls.
